(19) United States
(12) Patent Application Publication
(10) Pub. No.: US 2007/0284634 A1
(43) Pub. Date: Dec. 13, 2007

(54) Semiconductor device and method of manufacturing the same

(75) Inventors: Shigeyuki Yokoyama, Tokyo (JP); Takuo Ohashi, Tokyo (JP); Shiro Uchiyama, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/785,948

(22) Filed: Apr. 23, 2007

(30) Foreign Application Priority Data
May 12, 2006 (JP) 2006-133413

(51) Int. Cl. H01L 29/94; H01L 21/336

(52) U.S. Cl. 257/288; 438/197; 257/E29.345; 257/E21.409

(57) ABSTRACT

A semiconductor device includes a convex portion of a first conductive type protruding from a semiconductor substrate between insulating films formed on the semiconductor substrate in an upper direction than the insulating films. A gate insulating film contains nitrogen and is formed on at least a portion of the convex portion. A gate electrode is formed on the gate insulating film to contain an impurity of a same conductive type as the first conductive type.

### BACKGROUND OF THE INVENTION

1. Field of the Invention

The present invention relates to a semiconductor device, and more particularly relates to a field effect transistor in which an active region is formed as a fin type.

2. Description of the Related Art

A field effect transistor in which an active region of a transistor is formed as a fin type is known (hereafter, referred to as FinFET).

FIG. 1 is a perspective view showing the structure of a conventional FinFET. A substrate 201 has a convex portion extending in a first direction. Device separation oxide films 202 are provided on both sides of the convex portion to extend in parallel to the convex portion in the first direction. A gate electrode 204 is formed on the convex section through a gate insulating film 203 to extend in a second direction. It should be noted that the second direction is a direction orthogonal to the first direction within a substrate flat surface. Source and drain region portions of the convex section on both sides of the gate electrode 204 in the first direction are doped with impurity. A semiconductor region of a conductive type opposite to that of the source and drain regions is formed in the convex portion below the gate electrode 204, and the semiconductor region functions as a channel region.

In the FinFET, it is possible to suppress a short channel effect, and it is possible to improve a sub-threshold characteristic of a transistor. Also, since the entire surface of the convex (fin) portion is used as a channel, an effective gate width can be increased. Thus, a drive current can be made larger than that of a planer type transistor having the same projection area.

However, in a memory cell transistor in DRAM, the channel region is required to be partially or fully depleted in order to accomplish a good sub-threshold characteristic and short channel suppression effect. If an impurity concentration is reduced to make generation of the depletion region easier, the threshold of the transistor becomes too low, which leads to the increase in a leakage current in the OFF state. Thus, when the FinFET is used as the memory cell transistor in the DRAM, there is a case that the good sub-threshold characteristic and short channel suppression effect are sacrificed.

In conjunction with the above description, Japanese Laid Open Patent Application (JP-P2000-196017A) discloses a technique that, while maintaining the high performance of MISFET in a logic circuit, the leakage current of a MISFET for selection of a memory cell in a DRAM is reduced.

Also, Japanese Laid Open Patent Application (JP-P2001-298194A) discloses a field effect transistor. In this conventional example, in order to give the high commonness to a conventional structure in source/drain regions and a gate electrode and a forming process and make application of a vertical field effect transistor to an LSI easy, electrical conduction paths are arranged on an insulating film to extend in a direction. The source/drain regions are provided in a direction orthogonal to the arrangement direction of the electrical conduction paths, and two source/drain regions are connected through the electrical conduction path. A gate electrode is formed in the center portion of a semiconductor layer constituting each electrical conduction path via an insulating film. Thus, the gate electrode is provided in the arrangement direction of the electrical conduction paths to stride over the plurality of electrical conduction paths. In each electrical conduction path, the planes of the semiconductor layer on its both sides are main conduction paths. The width of each electrical conduction path is wide in a portion in contact with the source/drain regions and narrow near a channel formation region.

### SUMMARY OF THE INVENTION

It is therefore an object of the present invention to provide a semiconductor device that can accomplish a high threshold voltage without deteriorating a good sub-threshold characteristic and short channel suppression effect, and a method of manufacturing the same.

In an aspect of the present invention, a semiconductor device includes a convex portion of a first conductive type protruding from a semiconductor substrate between insulating films formed on the semiconductor substrate in an upper direction than the insulating films; a gate insulating film containing nitrogen and formed on at least a portion of the convex portion; and a gate electrode formed on the gate insulating film to contain an impurity of a same conductive type as the first conductive type.

Here, the convex portion has a surface well region of the first conductive type. The semiconductor device may further include source and drain regions of formed in the convex portion on both sides of the gate insulating film, and the source and drain regions are of a second conductive type opposite to the first conductive type.

Also, the semiconductor device may further include an impurity doped layer provided between the convex portion and the gate insulating film, to contain an impurity of a second conductive type opposite to the first conductive type.

Also, the first conductive type may be a P type, and the second conductive type may be an N-type.

Also, the gate electrode may be formed of boron-doped polysilicon.

Also, the gate insulating film may have a 2-layer structure of first and second layers, and one of the first and second layers is a nitride layer.

In this case, the first layer may include a silicon oxide film formed on the convex portion, and the second layer may include a silicon nitride film formed on the silicon oxide film.

Also, the silicon nitride film may be an oxynitride film.

Also, the gate insulating film may include an oxynitride film.

In another aspect of the present invention, a method of manufacturing a semiconductor device is achieved by forming a convex portion of a first conductive type as a semiconductor layer on a semiconductor substrate such that the convex portion extends to an upper direction from the semiconductor substrate; by forming on at least a portion of the convex portion, an impurity doped layer in which an impurity of a second conductive type opposite to the first conductive type is doped; by forming a gate insulating film on the impurity doped layer of the convex portion; and by forming on the gate insulting film, a gate electrode in which an impurity of the first conductive type is doped.

Here, the first conduction type may be a P type and the second conductive type may be an N type.

Also, the forming a gate electrode may be achieved by forming the gate electrode of boron-doped polysilicon.

Also, the forming a gate insulating film may be achieved by forming the gate insulating film to have a 2-layer structure.

Also, the forming a gate insulating film may be achieved by depositing a silicon oxide film on the impurity doped layer of the convex portion; and by depositing a silicon nitride film on the silicon oxide film.

In this case, the depositing a silicon nitride film may be achieved by depositing the silicon nitride film by an atomic layer deposition method.

Also, the forming a gate insulating film may be achieved by forming an oxynitride film as the gate insulating film. In this case, the forming a gate insulating film may be achieved by forming the oxynitride film by a substrate bias plasma nitride method.

### BRIEF DESCRIPTION OF THE DRAWINGS

FIG. 1 is a perspective view showing a conventional semiconductor device;

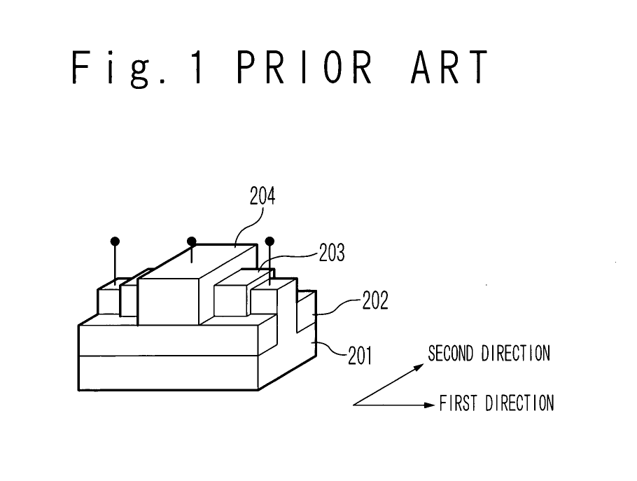

FIGS. 2A and 2B are a perspective view and a sectional view of a semiconductor device according to the present invention, respectively;

FIGS. 3A to 3E are perspective views in a process for manufacturing the semiconductor device according to the present invention; and

FIG. 4 is a flow chart showing a method of manufacturing the semiconductor device according to the present invention.

### DESCRIPTION OF THE PREFERRED EMBODIMENTS

Hereinafter, a semiconductor device according to the present invention will be described in detail with reference to the attached drawings.

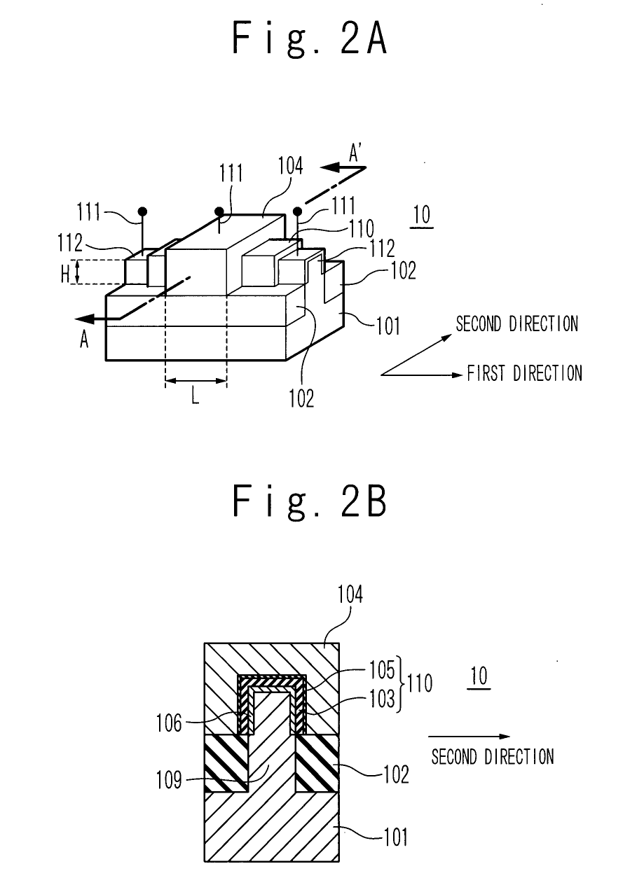

The semiconductor device according to an embodiment of the present invention will be described by exemplifying a memory cell transistor in DRAM as a semiconductor device 10. The memory cell transistor in the DRAM is required to have a high threshold voltage. Also, it is required to have a low leakage current in an OFF state of the memory cell transistor. FIG. 2A is a perspective view showing the configuration of the semiconductor device 10 in this embodiment and FIG. 2B is a sectional view of the semiconductor device 10 along the line A-A′ in FIG. 2A.

The semiconductor device 10 has a silicon substrate 101, device separating oxide films 102, a gate insulating film 110, a gate electrode 104 and contacts 111. A convex portion 109 is provided on the silicon substrate 101. The convex portion 109 may be stacked on the substrate 101 or formed as a part of the substrate 101. The convex portion 109 is provided to extend in a first direction, as shown in FIG. 2A. The convex portion 109 is a semiconductor layer in which P-type impurity such as B⁺ and BF₂⁺ is doped.

The device separating oxide films 102 are formed on both sides of the convex portion 109 on the silicon substrate 101 to extend in the first direction. The height of the device separating oxide film 102 is lower than the height of the convex portion 109. Therefore, the upper portion of the convex portion 109 upwardly protrudes from the device separating oxide films 102. The height H of the convex portion 109 protruding from the device separating oxide film 102 is in a range of 10 and 100 nm. The device separating oxide film 102 is a silicon oxide film.

An impurity doped layer 106 is formed in a surface portion i.e., side surface portions and an upper surface portion, of the convex portion 109 protruding from the device separating oxide films 102 between source and drain regions 112. The impurity doped layer 106 is a semiconductor layer in which N-type impurity such as P⁺ and As⁺ is doped. An amount of the N-type impurity doped in the impurity doped layer 106 is determined in accordance with a required threshold voltage.

The gate insulating film 110 is provided to cover a part of the surface portion of the convex portion 109, i.e., the side surfaces portions and the upper surface portion of the convex portion 109. The convex portion 109 on the silicon substrate 101 is exposed on both sides of the gate insulating film 110 in the first direction. The exposed portions of the convex portion 109 serve as the source and drain regions 112 in which P-type impurity is doped. A silicon oxide film 103 is formed on the impurity doped layer 106 to cover the surface portion of the convex portion 109 and a silicon nitride film 105 is laminated on the silicon oxide film 103. Thus, the gate insulating film 110 has a 2-layer structure, as shown in FIG. 2B. In this way, since the gate insulating film 110 has the 2-layer structure, it is possible to suppress the diffusion of boron when the gate electrode is formed, which will be described later. It should be noted that the gate insulating film 110 may be a silicon oxynitride film of a single-layer structure. The silicon oxynitride film can prevent the boron ions from being diffused when the gate electrode is formed.

The gate electrode 104 is provided on a part of the convex portion 109 through the gate insulating film 100 to cover the part of the gate insulating film 100. The length of the gate electrode 104 in the first direction is shorter than the length of the gate insulating film 110. That is, the gate insulating film 110 is configured to project from the both sides of the gate electrode 104 in the first direction. It should be noted that the length L of the gate electrode 104 is in a range of 10 and 100 nm, for example. The gate electrode 104 is a P-type polysilicon film in which boron ions are doped.

Each of the contacts 111 is connected onto one of the gate electrode 104 and the source and drain regions 112. It should be noted that the contacts 111 are formed to be embedded in an inter-layer insulating film (not shown).

The semiconductor device 10 according to this embodiment is a FinFET having the above convex (fin) portion. The P-type polysilicon film is used as the gate electrode 104, and the impurity doped layer 106 of the N-type is provided between an active region and the gate insulating film 110. Thus, the threshold voltage can be set to a desirable value depending on the impurity concentration of the impurity doped layer 106. At this time, the conductive type of the impurity doped layer 106 is opposite to that of the region outside the impurity doped layer 106. Therefore, the width of a depletion layer formed when a bias is applied to the gate electrode can be made wider. Thus, while maintaining the desirable threshold voltage, it becomes easy to deplete the channel region. Also, when the P-type polysilicon is used for the gate electrode 104, there is a fear that the impurity ions doped into the gate electrode 104 diffuse through the gate insulating film into the channel region to vary the threshold voltage. However, since the structure of the gate insulating film 110 is devised, the diffusion is suppressed.

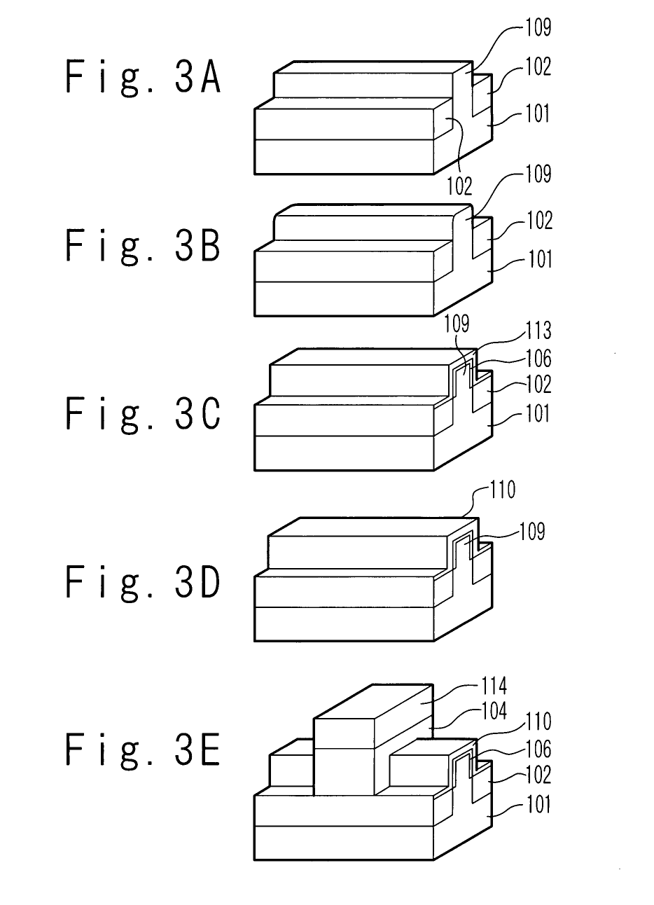

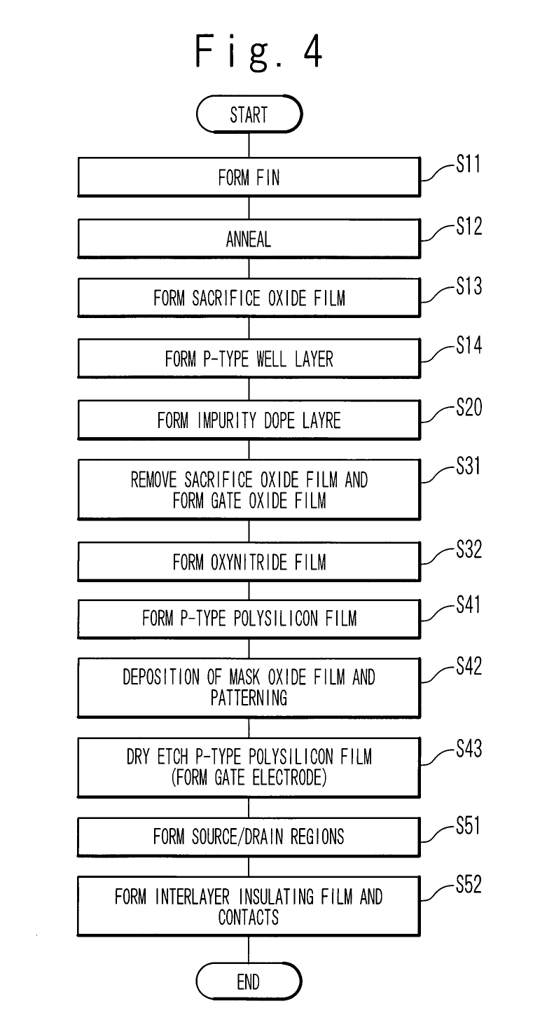

Next, a method of manufacturing the semiconductor device according to this embodiment will be described. FIG. 4 is flow chart showing a flow of the method of manufacturing the semiconductor device. The respective steps will be described below in detail with reference to FIGS. 3A to 3E.

### Step S11: Formation of Fin

The device separating oxide films 102 are formed on the silicon substrate 101 as silicon oxide films and removed to dig down by etching, so that a part of the silicon substrate is protruded from the device separating oxide films 102 to form a fin structure. Thus, the convex portion 109 is formed. FIG. 3A shows a perspective view at this time.

### Step S12: Annealing

A thermal process (annealing) is carried out in hydrogen atmosphere. Consequently, the corner of the convex portion 109 is rounded. In this way, since the corner is rounded, the convergence of the electric field can be protected. FIG. 2B shows a perspective view showing the situation that the corner is rounded.

### Step S13: Formation of Sacrifice Oxide Film

Subsequently, the surface portion of the convex portion 109 is oxidized. A sacrifice oxide film 113 is formed to have the film thickness of several nm (step S13). The sacrifice oxide film 113 is preferably formed through In-Situ Steam Generation (ISSG) oxidization in which the plane direction dependence of an oxidization rate is very small, or plasma oxidization. Since the oxidization is performed by such a method, the sacrifice oxide film 113 can be uniformly formed on the top surface and side surfaces of the convex portion 109.

### Step S14: Formation of P-type Semiconductor Layer

Subsequently, the P-type impurity ions are implanted into the convex portion 109. Thus, a P-type well layer (P-type semiconductor layer) is formed in the convex portion 109 (step S14).

### Step S20: Formation of Impurity Doped Layer

Subsequently, the N-type impurity ions are implanted into the upper surface portion and side surface portions of the convex portion 109. Consequently, the impurity doped layer 106 is formed. At this time, the N-type impurity ions are preferably implanted at a certain angle with respect to the surface of the substrate 101, and the N-type impurity ions are not implanted from a vertical direction. Since the impurity ions are implanted at the certain angle, the impurity doped layer 106 can be uniformly formed on the upper surface portion and side surface portions of the convex portion 109. FIG. 2C shows the perspective view after the formation of the impurity doped layer 106.

### Step S31: Removal of Sacrifice Oxide Film and Formation of Silicon Oxide Film

Subsequently, a wet etching is carried out to remove the sacrifice oxide film 113. Then, the silicon oxide film 103 is deposited to cover the upper surface and side surfaces of the convex portion 109 and the surfaces of the device separating oxide film 102. Several nm are exemplified as the film thickness of the silicon oxide film 103. The oxidization at this time is preferably performed by the ISSG oxidization or plasma oxidization, similarly to the formation of the sacrifice oxide film as mentioned above, in order to attain the uniform formation of the convex portion 109.

### Step S32: Formation of Oxide Nitride Film

Subsequently, the silicon oxynitride film 105 is formed on the silicon oxide film 103. The silicon oxynitride film is formed by a substrate bias plasma nitriding method. The substrate bias plasma nitriding method is a method of applying the bias to the silicon substrate 101 and depositing the silicon oxynitride film 105. In a usual plasma nitriding method, since the bias is not applied to the substrate side, it is difficult to uniformly oxynitride the upper and side surfaces of the convex portion 109. However, through the application of the bias to the substrate side, the silicon oxide nitride film can be uniformly deposited. FIG. 2D shows a perspective view after the silicon oxynitride film 105 is deposited. It should be noted that FIG. 2D shows the silicon oxide film 103 and the silicon oxynitride film 105 as the gate insulating film 110.

In the process of S32, the silicon oxynitride film 105 may be replaced with the silicon nitride film having the film thickness of several nm formed by an atomic layer deposition (ALD method). If the gate electrode side of the gate insulating film 110 is formed from the silicon nitride film or silicon oxynitride film, it is possible to suppress the diffusion of the impurity (boron) ions doped into the gate electrode. Also, since the ALD method is excellent in the covering property, the silicon nitride film can be uniformly deposited in the convex portion 109.

### Step S41: Formation of P-type Polycrystalline Silicon

Subsequently, a non-doped polysilicon film is deposited on the gate insulating film 110. About 100 nm is exemplified as its thickness of the polysilicon film. Then, as the P-type impurity, the boron ions are implanted into the non-doped polysilicon film. Consequently, the P-type polysilicon film is formed.

### Step S42: Deposition and Patterning of Mask Oxide Film

A mask oxide film 114 is formed on the P-type polysilicon film deposited by the process of S41. The film thickness of the mask oxide film 114 is exemplified between 10 nm and 100 nm. After the deposition of the mask oxide film 114, a lithography technique is used to pattern the mask oxide film 114, and only the mask oxide film 114 is left on the convex portion 109 in the first direction.

### Step S43: Dry Etching of P-type Polysilicon

Subsequently, the patterned mask oxide film 114 is used as the mask, and the P-type polysilicon film is dry-etched. Consequently, the gate electrode 104 is formed.

It should be noted that after the formation of the gate electrode 104, the oxidizing process may be performed to form a bird's beak where the thickness of the gate insulating film at end portions of the gate electrode is relatively thick. Through the formation of the bird's beak, electric field in the drain end on the operation can be relaxed.

### Step S51: Formation of Source and Drain Regions

### Step S51: Formation of Source/Drain regions

Next, the gate insulating film 10 is removed on the both sides in the first direction. Then, a mask oxide film is form as a mask by the lithography technique. The N-type impurity ions are implanted into the portions of the convex portion 109 from which the gate insulating film is removed, to form the source and drain regions on both the sides of the gate electrode 104 in the first direction. It should be noted that the implantation of the N-type impurity ions at this time is not required to be the ion implantation. For example, plasma doping can be also used.

Also, at a step S51, the ion implantation of a relatively low concentration is firstly performed. Subsequently, the nitride film of several 10 nm is deposited and etched back, and then the ion implantation of a high concentration is performed. Thus, it is possible to get a lightly doped drain (LDD) structure in which the low concentration regions are formed between the respective source and drain regions and the channel region. In this way, through employment of the LDD structure, it is possible to relax the electric field in the end portions.

### Step S52: Formation of Inter-layer Insulating Film and Contact

Moreover, after the inter-layer insulating film is grown, the contacts are connected to the gate electrode and the respective source and drain regions, and the FinFET is obtained.

As mentioned above, according to this embodiment, the P-type polysilicon film is used as the gate electrode, and the N-type impurity doped layer is provided between the gate insulating film and the channel region, to adjust the threshold voltage. Thus, in addition to the achievement of the desirable threshold voltage, the channel region can be easily depleted.

Also, since the gate insulating film includes the silicon nitride film or silicon oxide film, it is possible to suppress the diffusion of the impurity ions when the P-type polysilicon film is used.

What is claimed is:

1. A semiconductor device comprising:
a convex portion of a first conductive type protruding from a semiconductor substrate between insulating films formed on said semiconductor substrate in an upper direction than said insulating films;
a gate insulating film containing nitrogen and formed on at least a portion of said convex portion; and
a gate electrode formed on said gate insulating film to contain an impurity of a same conductive type as said first conductive type.

2. The semiconductor device according to claim 1, wherein said convex portion has a surface well region of said first conductive type,
said semiconductor device further comprises:
source and drain regions of formed in said convex portion on both sides of said gate insulating film, and
said source and drain regions are of a second conductive type opposite to said first conductive type.

3. The semiconductor device according to claim 1, further comprising:
an impurity doped layer provided between said convex portion and said gate insulating film, to contain an impurity of a second conductive type opposite to said first conductive type.

4. The semiconductor device according to claim 2, wherein said first conductive type is a P type, and said second conductive type is an N-type.

5. The semiconductor device according to claim 1, wherein said gate electrode is formed of boron-doped polysilicon.

6. The semiconductor device according to claim 1, wherein said gate insulating film has a 2-layer structure of first and second layers, and one of said first and second layers is a nitride layer.

7. The semiconductor device according to claim 6, wherein said first layer comprises a silicon oxide film formed on said convex portion, and
said second layer comprises a silicon nitride film formed on said silicon oxide film.

8. The semiconductor device according to claim 7, wherein said silicon nitride film is an oxynitride film.

9. The semiconductor device according to claim 1, wherein said gate insulating film comprises an oxynitride film.

10. A method of manufacturing a semiconductor device, comprising:
forming a convex portion of a first conductive type as a semiconductor layer on a semiconductor substrate such that said convex portion extends to an upper direction from said semiconductor substrate;
forming on at least a portion of said convex portion, an impurity doped layer in which an impurity of a second conductive type opposite to said first conductive type is doped;
forming a gate insulating film on said impurity doped layer of said convex portion; and
forming on said gate insulting film, a gate electrode in which an impurity of said first conductive type is doped.

11. The method according to claim 10, wherein said first conduction type is a P type and said second conductive type is an N type.

12. The method according to claim 11, wherein said forming a gate electrode comprises:
forming said gate electrode of boron-doped polysilicon.

13. The method according to claim 10, wherein said forming a gate insulating film comprises:
forming said gate insulating film to have a 2-layer structure.

14. The method according to claim 13, wherein said forming a gate insulating film comprises:
depositing a silicon oxide film on said impurity doped layer of said convex portion; and
depositing a silicon nitride film on said silicon oxide film.

15. The method according to claim 14, wherein said depositing a silicon nitride film comprises:
depositing said silicon nitride film by an atomic layer deposition method.

16. The method according to claim 10, wherein said forming a gate insulating film comprises:
forming an oxynitride film as said gate insulating film.

17. The method according to claim 16, wherein said forming a gate insulating film comprises:
forming said oxynitride film by a substrate bias plasma nitride method.
